(19) United States
(12) Patent Application Publication
(10) Pub. No.: US 2014/0183589 A1
(43) Pub. Date: Jul. 3, 2014

(54) METHOD FOR MANUFACTURING A SEMICONDUCTOR LIGHT-EMITTING ELEMENT AND SEMICONDUCTOR LIGHT-EMITTING ELEMENT MANUFACTURED THEREBY

(71) Applicants: Jae Ho Han, Daejeon (KR); Sung Tae Kim, Seoul (KR); Seung Wan Chae, Yongin-si (KR); Jong Ho Lee, Seoul (KR); Je Won Kim, Seoul (KR)

(72) Inventors: Jae Ho Han, Daejeon (KR); Sung Tae Kim, Seoul (KR); Seung Wan Chae, Yongin-si (KR); Jong Ho Lee, Seoul (KR); Je Won Kim, Seoul (KR)

(73) Assignee: SAMSUNG ELECTRONICS CO., LTD., Suwon-si, Gyeonggi-do (KR)

(21) Appl. No.: 14/237,515

(22) PCT Filed: Aug. 9, 2011
(86) PCT No.: PCT/KR2011/005777

§ 371 Date: Feb. 6, 2014

(51) Int. Cl. H01L 33/00; H01L 33/60

(52) U.S. Cl. CPC H01L 33/005; H01L 33/60
USPC 257/98; 438/29

(57) ABSTRACT

There are provided a method of manufacturing a semiconductor light emitting device and a semiconductor light emitting device manufactured thereby. According to an exemplary embodiment, a method of manufacturing a semiconductor light emitting device includes: forming a light emitting structure by sequentially growing a first conductivity type semiconductor layer, an active layer and a second conductivity type semiconductor layer on a first main surface of a substrate, the substrate having first and second main surfaces opposing one another; forming a reflective film on the second main surface of the substrate, the reflective film including at least one laser absorption region; and performing a scribing process separating the light emitting structure and the substrate into device units by irradiating a laser from a portion of a top of the light emitting structure corresponding to the laser absorption region to the light emitting structure and the substrate.

### TECHNICAL FIELD

The present disclosure relates to a method of manufacturing a semiconductor light emitting device and a semiconductor light emitting device manufactured thereby, and more particularly, to a method of manufacturing a semiconductor light emitting device which may minimize damages to a light emitting structure during a scribing process for separating device units.

### BACKGROUND ART

A semiconductor light emitting device is a semiconductor device able to emit light of various colors through electron-hole recombination occurring at p-n junctions between p-type and n-type semiconductors when current is applied thereto. A semiconductor light emitting device has various advantages over a filament-based light emitting device, such as a relatively long lifespan, relatively low power consumption, superior initial-operating characteristics, high vibration resistance, and the like; accordingly, the demand for semiconductor light emitting devices has continued to grow. In particular, recently, a group III-nitride semiconductor capable of emitting short-wavelength blue light has drawn attention.

In the case of a general semiconductor light emitting device, a light emitting structure is formed by sequentially growing an n-type semiconductor layer, an active layer and a p-type semiconductor layer on one surface of a substrate, followed by separating the light emitting structure into device units through a scribing process. The scribing process may be performed through mechanical scribing using a diamond tip or laser scribing. In a case in which a metallic reflective film is applied to the other surface of the substrate, the mechanical scribing may be impracticable because it is difficult to form a groove in a soft metal plate using a diamond tip. The laser scribing may be used even when the metallic reflective film is applied to the other surface of the substrate; however, debris caused by a laser beam during the scribing process may be adsorbed onto the light emitting structure, especially to sides of the light emitting structure, or a crystalline structure change may occur, and such a region of the light emitting structure may act as a light absorption layer, resulting in a reduction in luminous efficiency.

### DISCLOSURE

### Technical Problem

An aspect of the present disclosure may provide a method of manufacturing a semiconductor light emitting device in which damages to a light emitting structure during a scribing process for separating device units may be minimized.

An aspect of the present disclosure may also provide a semiconductor light emitting device manufactured by the above method.

### Technical Solution

According to an aspect of the present disclosure, a method of manufacturing a semiconductor light emitting device may include: forming a light emitting structure by sequentially growing a first conductivity type semiconductor layer, an active layer and a second conductivity type semiconductor layer on a first main surface of a substrate, the substrate having first and second main surfaces opposing one another; forming a reflective film on the second main surface of the substrate, the reflective film including at least one laser absorption region; and performing a scribing process separating the light emitting structure and the substrate into device units by irradiating a laser from a portion of a top of the light emitting structure corresponding to the laser absorption region to the light emitting structure and the substrate.

The method may further include: removing a portion of the light emitting structure in two or more regions thereof to expose a portion of the first conductivity type semiconductor layer for each device unit; forming a first electrode on the exposed portion of the first conductivity type semiconductor layer; and forming a second electrode on the second conductivity type semiconductor layer.

A region of the reflective film, excluding the light absorption region, may be made of a material including Ag or Al.

The laser may have a wavelength of 800 nm to 1200 nm.

The light absorption region may be made of a single metal or an alloy.

The light absorption region may be made of a metallic oxide.

The light absorption region may be made of a material selected from the group consisting of C, Cu and Ti.

The method may further include performing a lapping process on the substrate before forming the reflective film.

According to another aspect of the present disclosure, a semiconductor light emitting device may include: a substrate having first and second main surfaces opposing one another; a light emitting structure formed on the first main surface of the substrate and including a first conductivity type semiconductor layer, an active layer and a second conductivity type semiconductor layer; a reflective film formed on the second main surface of the substrate; and a laser absorption region formed on a side of the reflective film.

A side of the laser absorption region may be on the same plane with that of the substrate and the light emitting structure.

The laser absorption region may be made of a material capable of absorbing a laser having a wavelength of 800 nm to 1200 nm.

The light absorption region may be made of a single metal or an alloy.

The light absorption region may be made of a metallic oxide.

The light absorption region may be made of a material selected from the group consisting of C, Cu and Ti.

The reflective film may be made of a material including Ag or Al.

### Advantageous Effects

When a method of manufacturing a semiconductor light emitting device according to exemplary embodiments of the present disclosure is used, a scribing process is performed using a stealth laser, whereby the formation of an undesirable light absorption layer on a side of a light emitting structure may be minimized. Therefore, the manufactured semiconductor light emitting device may have improved reliability and luminous efficiency.

### DESCRIPTION OF DRAWINGS

FIGS. 1 through 7 are cross-sectional views illustrating a method of manufacturing a semiconductor light emitting device according to an exemplary embodiment of the present disclosure; and

FIG. 8 is a cross-sectional view illustrating a semiconductor light emitting device according to an exemplary embodiment of the present disclosure.

### BEST MODE

Hereinafter, embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity.

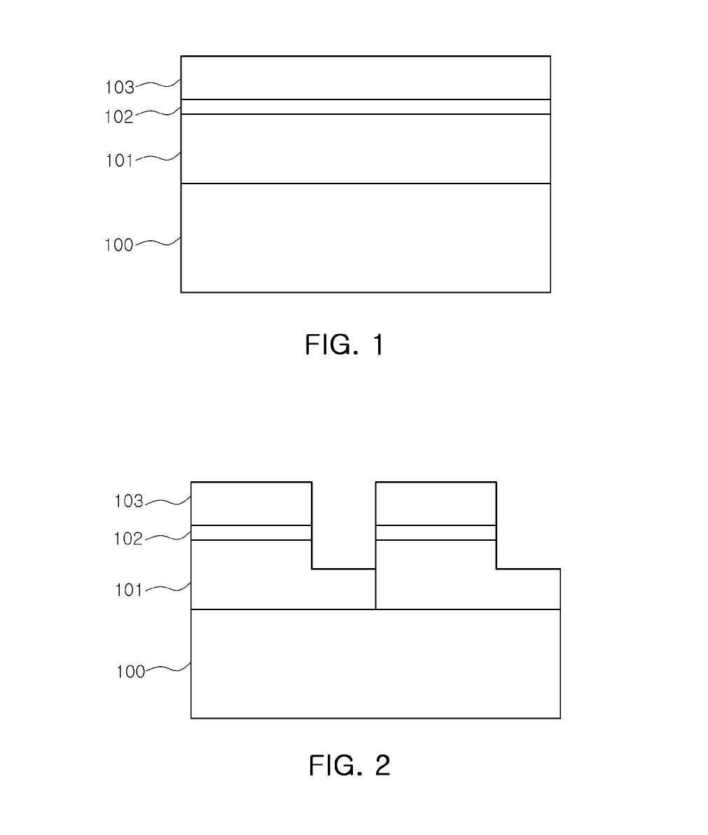

FIGS. 1 through 7 are cross-sectional views illustrating a method of manufacturing a semiconductor light emitting device according to an exemplary embodiment of the present disclosure. FIG. 8 is a cross-sectional view illustrating a semiconductor light emitting device according to an exemplary embodiment of the present disclosure having a structure obtained by the method proposed according to the present inventive concept.

In a method of manufacturing a semiconductor light emitting device according to an exemplary embodiment of the present disclosure, as illustrated in FIG. 1, a substrate 100 having first and second main surfaces opposing each other may be prepared, and a first conductivity type semiconductor layer 101, an active layer 102 and a second conductivity type semiconductor layer 103 may be sequentially formed on the first main surface of the substrate 100. In this case, the first conductivity type semiconductor layer 101, the active layer 102 and the second conductivity type semiconductor layer 103 may form a light emitting structure. In the present embodiment, the light emitting structure may be divided into a plurality of light emitting devices by a scribing process.

The substrate 100 may be a semiconductor growth substrate, and may be made of a material having electrical insulating and conductive properties, such as sapphire, SiC, MgAl₂O₄, MgO, LiAlO₂, LiGaO₂, GaN or the like. In the case in which the substrate 100 made of sapphire having electrical insulating properties is used, an etching process is needed to form an electrode to be connected to the first conductivity type semiconductor layer 101. Sapphire is a crystal having Hexa-Rhombo R3c symmetry and has a lattice constant of 13.001 Å along a C-axis and a lattice constant of 4.758 Å along an A-axis. Crystal planes of sapphire include a C (0001) plane, an A (1120) plane, an R (1102) plane, and the like. The C plane is mainly used as a substrate for nitride semiconductor growth because it facilitates the growth of a nitride film and is stable at high temperatures.

The first and second conductivity type semiconductor layers 101 and 103 may be n-type and p-type semiconductor layers made of nitride semiconductors, respectively. The present inventive concept is not limited thereto; however, according to the present embodiment, the first and second conductivity type semiconductor layers 101 and 103 may be understood as n-type and p-type semiconductor layers, respectively. The first and second conductivity type semiconductor layers 101 and 103 may be made of a material having a composition of AlₓIn_{y}Ga_{(1-x-y)}N, where 0≦x≦1, 0≦y≦1 and 0≦x+y≦1. For example, GaN, AlGaN, InGaN, or the like, may be used therefor. The active layer 102 formed between the first and second conductivity type semiconductor layers 101 and 103 emits light having a predetermined level of energy through recombination of electrons and holes, and may have a multi-quantum-well (MQW) structure, for example, an InGaN/GaN structure, in which quantum barrier layers and quantum well layers are alternately stacked. The first and second conductivity type semiconductor layers 101 and 103 and the active layer 102 forming the light emitting structure may be formed using growth processes known in the art such as metal organic chemical vapor deposition (MOCVD), molecular beam epitaxy (MBE), hydride vapor phase epitaxy (HVPE), or the like.

Next, as illustrated in FIG. 2, a portion of the light emitting structure is removed to expose a portion of the first conductivity type semiconductor layer 101. Here, the number of exposed portions of the first conductivity type semiconductor layer 101 corresponds to the number of light emitting device units. In order to remove the portion of the light emitting structure, an etching process such as inductively coupled plasma-reactive ion etching (ICP-RIE), or the like, may be appropriately used. This process is intended to form an electrode by exposing the first conductivity type semiconductor layer 101. If there is no need to expose the first conductivity type semiconductor layer 101, for example, if the substrate 100 is a conductive substrate, the etching process may be omitted. Meanwhile, FIG. 2 illustrates two light emitting devices formed on the substrate 100; however, it would be obvious to a person having ordinary skill in the art that three or more light emitting devices may be formed.

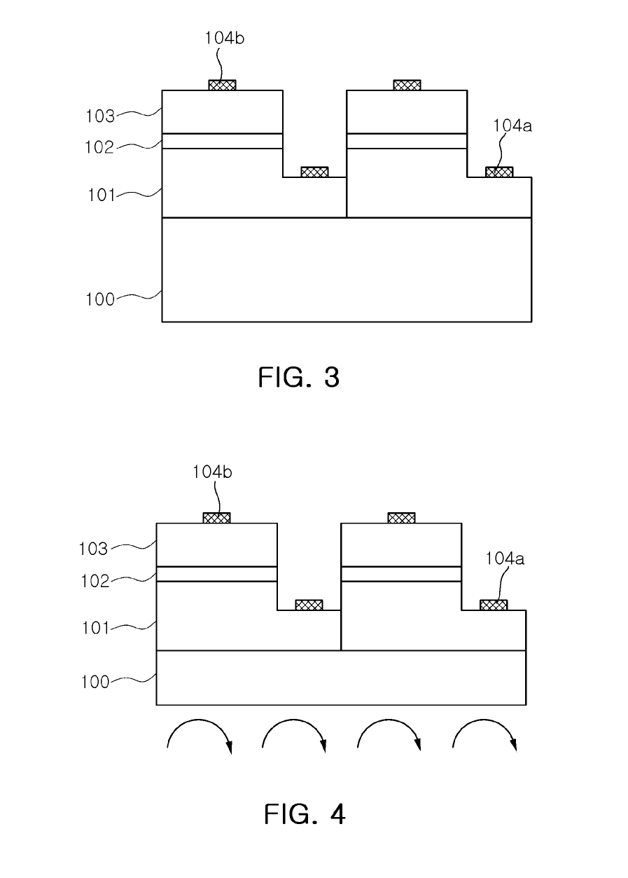

Then, as illustrated in FIG. 3, a first electrode 104a may be formed on the exposed surface of the first conductivity type semiconductor layer 101, and a second electrode 104b may be formed on the second conductivity type semiconductor layer 103. The first and second electrodes 104a and 104b may each have a multilayer electrode structure including a portion forming ohmic contact with the respective first and second conductivity type semiconductor layers 101 and 103 and a bonding pad portion. The first and second electrodes 104a and 104b may be formed by depositing or sputtering a selected metallic material. In this case, although not illustrated, a transparent electrode made of indium tin oxide (ITO), or the like, may be formed between the second conductivity type semiconductor layer 103 and the second electrode 104b in order to improve ohmic contact and current distribution.

Thereafter, as illustrated in FIG. 4, the substrate 100 may be subjected to a lapping process such that a thickness thereof is reduced. The lapping process is intended to decrease the size of a final light emitting device by decreasing the thickness of the substrate 100 included therein and to improve heat dissipation efficiency, and may be performed on the second main surface of the substrate 100. The lapping process is not necessarily required, and may be omitted if the substrate 100 is originally thin.

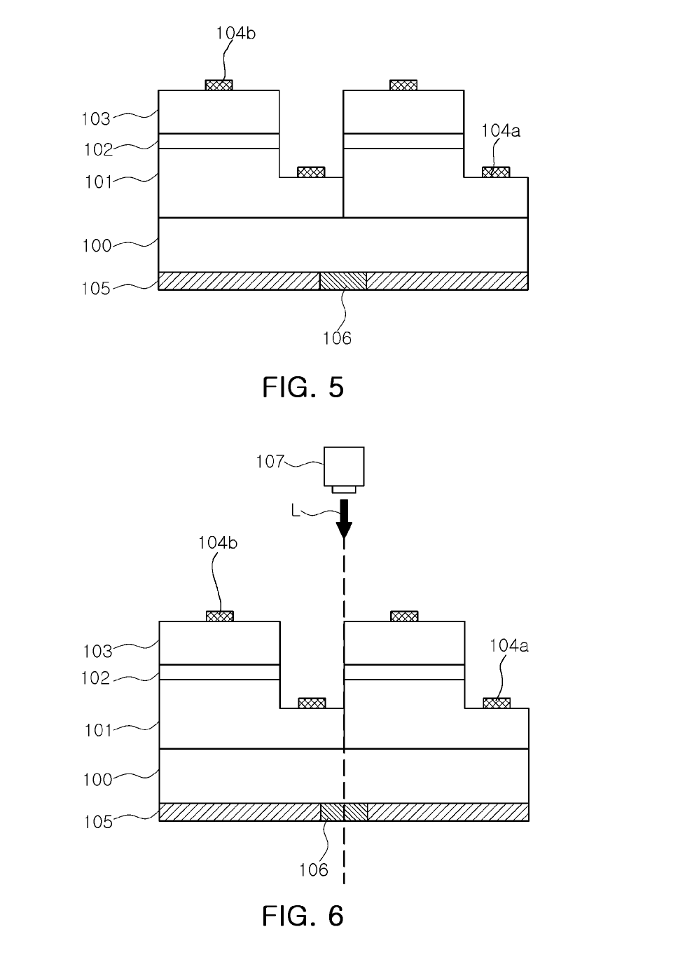

Then, as illustrated in FIG. 5, a reflective film 105 may be formed on the second main surface of the substrate 100, and a portion thereof may form a laser absorption region 106 using a different material. The reflective film 105 may be made of a metallic material having relatively high light reflectivity such as Ag, Al or the like, and may be formed by depositing such a metallic material on a surface of the substrate 100 excluding the laser absorption region 106 or bonding a thin reflective film thereto. The reflective film 105 made of the high reflective material may serve to upwardly reflect light emitted from the light emitting device, particularly from the active layer 102. The laser absorption region 106 may be formed in a scribing region for separating device units, and may be made of a material for absorbing a laser during the laser scribing process. In the present embodiment, a laser having a relatively long wavelength, for example, a stealth laser having a wavelength of approximately 800 nm to 1200 nm, is used, and thus, the laser absorption region 106 may be made of a material for absorbing such a stealth laser. The laser absorption region 106 may be made of a metal or an alloy, and any material capable of absorbing the laser may be used therefor. For example, the laser absorption region 106 may be made of a metallic oxide, C, Cu, Ti, or the like.

Then, as illustrated in FIG. 6, a laser scribing process may be performed to divide the continuous light emitting structure into light emitting device units. As described above, a laser light source 107 in the present embodiment may provide a stealth laser L having a wavelength of approximately 800 nm to 1200 nm and irradiate the laser to the light emitting structure and the substrate 100. Here, the opposite side of the reflective film 105 and the laser absorption region 106, that is, a portion of the top of the light emitting structure corresponding to the laser absorption region 106 may be irradiated with the laser. In the case in which the scribing process is performed using the stealth laser L, debris adsorbed onto the light emitting structure or crystalline structure change of the material forming the light emitting structure may be significantly reduced as compared to a case in which an ultraviolet (UV) laser is used.

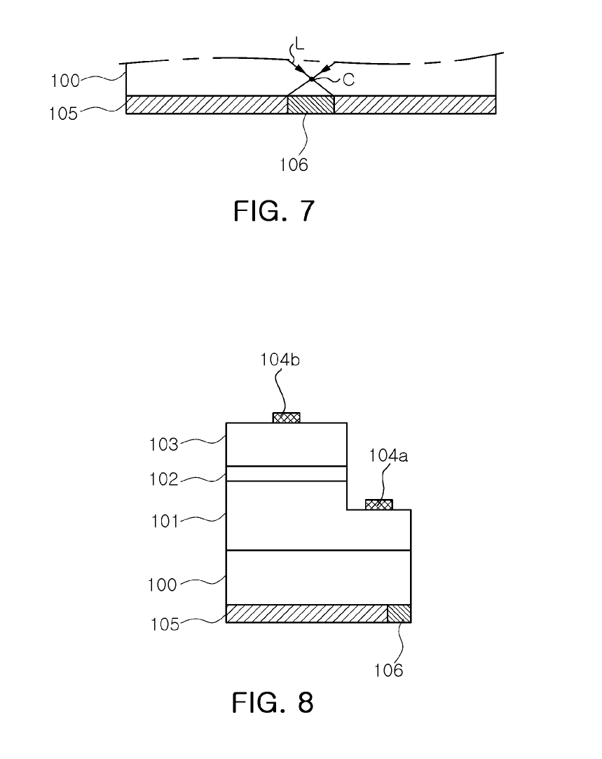

However, in the scribing process using the stealth laser L, if the stealth laser L is reflected by the high reflective material such as Ag, Al or the like, focus may fail to form, rendering the scribing process impracticable. In the present embodiment, the laser absorption region 106 made of the material capable of absorbing the stealth laser L is formed on a portion of the second main surface of the substrate 100 corresponding to the scribing region irradiated with the stealth laser L; thus, as illustrated in FIG. 7, a focus C of the stealth laser L may be formed inside the light emitting structure or the substrate 100. Therefore, the scribing process according to the present embodiment may separate device units relatively easily, and may minimize potential damages to the performance of the light emitting structure.

Meanwhile, the light emitting device units separated by the scribing process are illustrated in FIG. 8. In the semiconductor light emitting device manufactured by the method proposed in the exemplary embodiment of the present disclosure, the reflective film 105 may be formed on the second main surface of the substrate 100, along with the laser absorption region 106 made of the material capable of absorbing the stealth laser L formed on the portion of the second main surface. In this case, as described above, since the laser absorption region 106 is positioned in the scribing region, a side of the laser absorption region 106 may be on the same plane with that of the light emitting structure and the substrate 100, as illustrated in FIG. 8.

While exemplary embodiments have been shown and described above, it will be apparent to those skilled in the art that modifications and variations could be made without departing from the spirit and scope of the present disclosure as defined by the appended claims.

1. A method of manufacturing a semiconductor light emitting device, the method comprising:
forming a light emitting structure by sequentially growing a first conductivity type semiconductor layer, an active layer and a second conductivity type semiconductor layer on a first main surface of a substrate, the substrate having first and second main surfaces opposing one another;
forming a reflective film on the second main surface of the substrate, the reflective film including at least one laser absorption region; and
performing a scribing process separating the light emitting structure and the substrate into device units by irradiating a laser from a location over a top surface of the light emitting structure to the light emitting structure and the substrate, the location corresponding to the laser absorption region.

2. The method of claim 1, further comprising:
removing a portion of the light emitting structure in two or more regions thereof to expose a portion of the first conductivity type semiconductor layer for each device unit;
forming a first electrode on the exposed portion of the first conductivity type semiconductor layer; and
forming a second electrode on the second conductivity type semiconductor layer.

3. The method of claim 1, wherein a region of the reflective film, excluding the light absorption region, is made of a material including Ag or Al.

4. The method of claim 1, wherein the laser has a wavelength of 800 nm to 1200 nm.

5. The method of claim 1, wherein the light absorption region is made of a single metal or an alloy.

6. The method of claim 1, wherein the light absorption region is made of a metallic oxide.

7. The method of claim 1, wherein the light absorption region is made of a material selected from the group consisting of C, Cu and Ti.

8. The method of claim 1, further comprising performing a lapping process on the substrate before forming the reflective film.

9. A semiconductor light emitting device, comprising:
a substrate having first and second main surfaces opposing one another;
a light emitting structure formed on the first main surface of the substrate and including a first conductivity type semiconductor layer, an active layer and a second conductivity type semiconductor layer;
a reflective film formed on the second main surface of the substrate; and
a laser absorption region formed on a side of the reflective film.

10. The semiconductor light emitting device of claim 9, wherein a side of the laser absorption region is on the same plane with that of the substrate and the light emitting structure.

11. The semiconductor light emitting device of claim 9, wherein the laser absorption region is made of a material capable of absorbing a laser having a wavelength of 800 nm to 1200 nm.

12. The semiconductor light emitting device of claim 9, wherein the light absorption region is made of a single metal or an alloy.

13. The semiconductor light emitting device of claim 9, wherein the light absorption region is made of a metallic oxide.

14. The semiconductor light emitting device of claim 9, wherein the light absorption region is made of a material selected from the group consisting of C, Cu and Ti.

15. The semiconductor light emitting device of claim 9, wherein the reflective film is made of a material including Ag or Al.
